(19) United States
(12) Patent Application Publication
(10) Pub. No.: US 2010/0052036 A1
(43) Pub. Date: Mar. 4, 2010

(54) MEMORY DEVICE AND MANUFACTURING METHOD THEREOF, AND SEMICONDUCTOR DEVICE

(75) Inventors: Cheng-Hong Lee, Hsinchu City (TW); Chih-Ming Chao, Hsinchu City (TW); Hann-Ping Hwang, Hsinchu City (TW); Che-Huai Hung, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: POWERCHIP SEMICONDUCTOR CORP., Hsinchu (TW)

(21) Appl. No.: 12/545,054

(22) Filed: Aug. 20, 2009

(30) Foreign Application Priority Data
Sep. 4, 2008 (TW) 97133965

(51) Int. Cl. H01L 29/788; H01L 21/8239; H01L 29/792

(52) U.S. Cl. 257/321; 438/591; 257/411; 257/510; 257/E21.645; 257/E21.423; 257/E29.309; 257/E29.3

(57) ABSTRACT

A semiconductor device disposed on a substrate is provided. The semiconductor device includes two isolation structures, a first conductive layer, a charge trapping layer, a second conductive layer and a gate dielectric layer. The two isolation structures are disposed in the substrate to define an active area. The second conductive layer across the two isolation structures is disposed on the substrate. The first conductive layer is disposed between the two isolation structures and between the second conductive layer and the substrate. The second conductive layer electrically connects with the first conductive layer. The charge trapping layer is disposed on the substrate. The gate dielectric layer is disposed between the first conductive layer and the substrate. An interface between the two isolation structures and the first conductive layer is covered by the charge trapping layer to restrain the kink effect.

### CROSS-REFERENCE TO RELATED APPLICATION

This application claims the priority benefit of Taiwan application serial no. 97133965, filed on Sep. 4, 2008. The entirety of the above-mentioned patent application is hereby incorporated by reference herein and made a part of specification.

### BACKGROUND OF THE INVENTION

1. Field of the Invention

The present invention relates to a memory device and a manufacturing method thereof, and a semiconductor device. More particularly, the present invention relates to a memory device and a manufacturing method thereof, and a semiconductor, which are capable of restraining the kink effect.

2. Description of Related Art

As semiconductor technology advances, dimensions of the semiconductor device have also continued miniaturizing. When dimensions of the device miniaturize into deep sub-micron, even more tiny dimensions, chances for adjacent devices to have short circuit would increase. Therefore, how to effectively isolate devices becomes a rather important issue. Generally, during the process, an isolation structure is added between devices to avoid short circuit. Nowadays, a more extensively used method is a shallow trench isolation (STI) structure process. Since the STI structure is usually the major key to reliability, such as affecting chances of current leakage, the STI structure process plays an important role in the advanced integrated circuit manufacturing technology.

In the conventional process of the shallow trench isolation structure, a pad oxide layer and a silicon nitride mask layer are sequentially formed on the substrate. Afterwards, a photolithography process is performed to define an area for forming trenches, and then the silicon nitride mask layer, the pad oxide layer and the substrate are sequentially etched by a dry etching process to form trenches in the substrate. An area surrounded by the trenches is an active area, where various active devices will be formed in subsequent processes.

Next, a silicon oxide layer is deposited on the substrate to fill up the trenches. Thereafter, a chemical mechanical polishing process is performed to remove the silicon oxide layer higher than the silicon nitride mask layer so as to form shallow trench isolation structures. Next, the silicon nitride mask layer and the pad oxide layer are removed.

However, during the process of the shallow trench isolation structures, removing the pad oxide layer and the mask layer would result in formation of a divot around a top edge corner of the shallow trench isolation structure. The divot would cause sub-threshold leakage current to devices in the integrated circuit, and the phenomenon is known as the kink effect. Abnormal kink effect downgrades the quality of devices, reduces yields of the process, and in turn lowers the reliability of the devices.

### SUMMARY OF THE INVENTION

The present invention provides a memory device and a manufacturing method thereof. In the memory device, a charge trapping layer is disposed in a select transistor to cover an interface between shallow trench isolation (STI) structures and a conductive layer so as to restrain the kink effect.

The present invention provides a semiconductor device in which a charge trapping layer is disposed to cover an interface between STI structures and a conductive layer so as to restrain the kink effect.

The present invention provides a memory device disposed on a substrate, and the memory device has a plurality of isolation structures, a memory unit, a select unit and a charge trapping layer. The plurality of isolation structures are disposed in the substrate. The substrate has a memory unit region and a select unit region. The memory unit is disposed in the memory unit region and has a tunneling dielectric layer, a floating gate, an inter-gate dielectric layer and a control gate sequentially disposed on the substrate. The select unit is disposed in the select unit region and has a gate dielectric layer, a first conductive layer and a second conductive layer sequentially disposed on the substrate. The charge trapping layer is disposed in the select unit region and has an opening to electrically connect the second conductive layer with the first conductive layer. The charge trapping layer at least covers an interface between the isolation structures and the first conductive layer.

According to an embodiment of the present invention, a material of the charge trapping layer is selected from a group consisting of silicon nitride, silicon oxynitride, aluminum oxide (Al₂O₃), hafnium oxide (HfOₓ) and zirconium oxide (ZrO).

According to an embodiment of the present invention, the charge trapping layer is a silicon oxide/silicon nitride/silicon oxide layer.

According to an embodiment of the present invention, a material of the charge trapping layer is the same as a material of the inter-gate dielectric layer.

According to an embodiment of the present invention, a material of the first conductive layer is the same as a material of the floating gate.

According to an embodiment of the present invention, a material of the second conductive layer is the same as a material of the control gate.

The present invention provides a manufacturing method of a memory device, and the manufacturing method includes following steps. First, a substrate is provided. The substrate has a memory unit region and a select unit region. A plurality of isolation structures have already been formed in the substrate. A dielectric layer and a first conductive layer have already been formed on the substrate between adjacent isolation structures. After forming the charge trapping layer on the substrate, a portion of the charge trapping layer in the select unit region is removed to form a first opening exposing the first conductive layer. The remaining charge trapping layer in the select unit region at least covers an interface between the isolation structures and the first conductive layer. Thereafter, a second conductive layer is formed on the substrate. Then, the second conductive layer, the charge trapping layer, the first conductive layer and the dielectric layer are patterned to form a memory unit in the memory unit region and form a select unit in the select unit region.

According to an embodiment of the present invention, a material of the charge trapping layer is selected from a group consisting of silicon nitride, silicon oxynitride, aluminum oxide (Al₂O₃), hafnium oxide (HfOₓ) and zirconium oxide (ZrO).

According to an embodiment of the present invention, the charge trapping layer is a silicon oxide/silicon nitride/silicon oxide layer.

According to an embodiment of the present invention, the charge trapping layer in the memory unit serves as an inter-gate dielectric layer.

According to an embodiment of the present invention, the step of forming the isolation structures in the substrate and forming the dielectric layer and the first conductive layer on the substrate between the adjacent isolation structures proceeds as follows. A dielectric material layer, a conductive material layer and a mask layer are formed on the substrate. Afterwards, the mask layer, the conductive material layer, the dielectric material layer and the substrate are patterned to form a plurality of trenches in the substrate. After filling in an insulating material layer in the trenches, a portion of the insulating material layer and the mask layer are removed to form the isolation structures.

According to an embodiment of the present invention, the substrate further includes a peripheral circuit region, and the manufacturing method of the memory device further includes following steps. In the step of removing a portion of the charge trapping layer in the select unit region, a portion of the charge trapping layer in the peripheral circuit region is simultaneously removed. The remaining charge trapping layer in the peripheral circuit region at least covers an interface between the isolation structures and the first conductive layer. Furthermore, a semiconductor device is formed in the peripheral circuit region simultaneously in the step of patterning the second conductive layer, the charge trapping layer, the first conductive layer and the dielectric layer.

The present invention provides a semiconductor device disposed on the substrate. The semiconductor device has two isolation structures, a first conductive layer, a second conductive layer, a charge trapping layer and a gate dielectric layer. The two isolation structures are disposed in the substrate. The second conductive layer is disposed on the substrate across the two isolation structures. The first conductive layer is disposed between the two isolation structures and between the second conductive layer and the substrate. The first conductive layer is electrically connected to the second conductive layer. The charge trapping layer is disposed on the substrate and at least covers an interface between the two isolation structures and the first conductive layer. The gate dielectric layer is disposed between the first conductive layer and the substrate.

According to an embodiment of the present invention, a material of the charge trapping layer is selected from a group consisting of silicon nitride, silicon oxynitride, aluminum oxide (Al₂O₃), hafnium oxide (HfOₓ) and zirconium oxide (ZrO).

According to an embodiment of the present invention, the charge trapping layer is silicon oxide/silicon nitride/silicon oxide layer.

In the memory device and the manufacturing method thereof in the present invention, since the interface between the isolation structures and the first conductive layer is covered by the charge trapping layer, negative charges are trapped in the charge trapping layer to seduce positive charges on a surface of the substrate and reduce an electrical field of the substrate contacting a top edge corner of the isolation structures so that the kink effect is restrained. When the charge trapping layer also serves as an inter-gate dielectric layer, the kink effect is restrained without changing the process of the memory device.

In the semiconductor device of the present invention, the interface between the isolation structures and the first conductive layer is covered by the charge trapping layer, and thus negative charges are trapped in the charge trapping layer to seduce positive charges on a surface of the substrate and reduce an electrical field of the substrate contacting a top edge corner of the isolation structures so that the kink effect is restrained.

In order to make the aforementioned and other objects, features and advantages of the present invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a top view of a memory device according to a preferred embodiment of the present invention.

FIG. 1B is a cross-sectional view of a memory device according to a preferred embodiment of the present invention.

FIGS. 2A through 2F are cross-sectional views showing a process of a memory device according to a preferred embodiment of the present invention.

### DESCRIPTION OF EMBODIMENTS

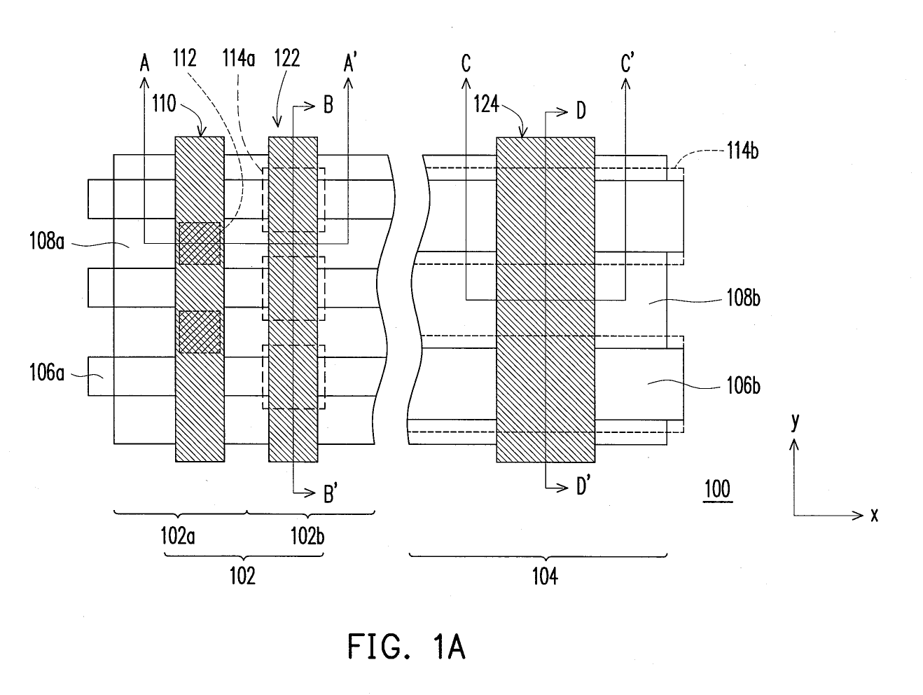

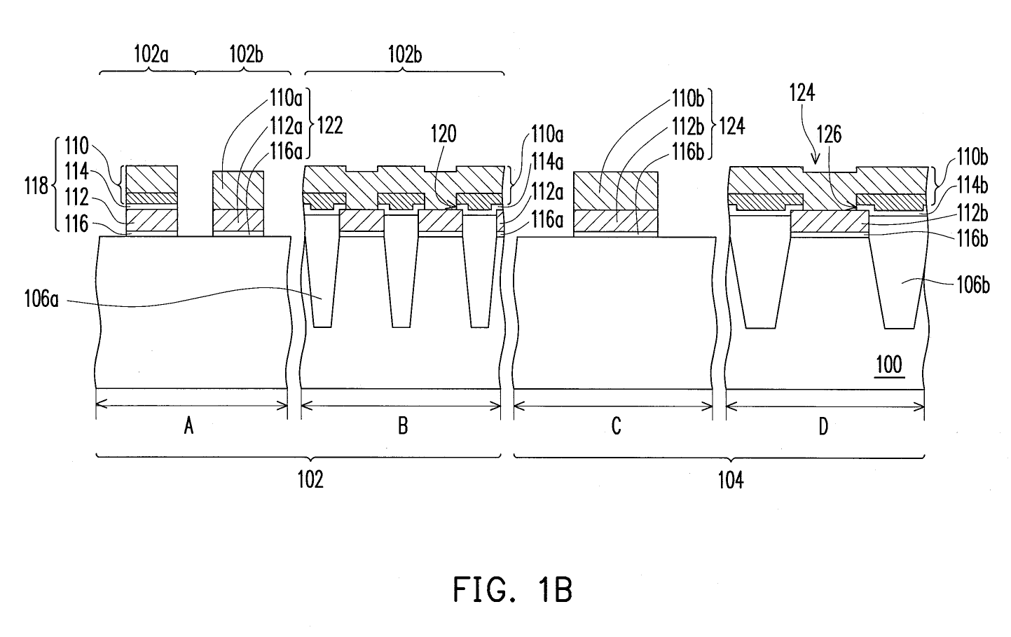

FIG. 1A is a top view of a memory device according to an embodiment of the present invention. FIG. 1B is a cross-sectional view of a memory device according to a preferred embodiment of the present invention. In FIG. 1B, a section A is a schematic cross-sectional view of FIG. 1A along sectioning lines A-A′. A section B is a schematic cross-sectional view of FIG. 1A along sectioning lines B-B′. A section C is a schematic cross-sectional view of FIG. 1A along sectioning lines C-C′. A section D is a schematic cross-sectional view of FIG. 1A along sectioning lines D-D′.

As shown by FIGS. 1A and 1B, the memory device is disposed on a substrate 100, for example. The substrate 100 is divided into a memory cell region 102 and a peripheral circuit region 104. The memory cell region 102 is again divided into a memory unit region 102a and a select unit region 102b. Isolation structures 106a and 106b are disposed in the substrate 100, for example, to define active areas 108a and 108b in the memory cell region 102 and the peripheral circuit region 104 respectively. The isolation structures 106a and 106b are disposed in parallel in the substrate 100, for example. The isolation structures 106a and 106b extend in an X direction, for example. The isolation structures 106a and 106b are shallow trench isolation (STI) structures, for example.

The memory unit region 102a has a memory unit 118. The memory unit 118 is constituted sequentially by the substrate 100, a tunneling dielectric layer 116, a floating gate 112, an inter-gate dielectric layer 114 and a control gate (word line) 110 from the substrate 100 upwards.

The control gate (word line) 110 extends in a Y direction. The Y direction and the X direction intersect, for example. The control gate (word line) 110 is constituted by two conductive layers, for example. Certainly, the control gate (word line) 110 may also be constituted by only one conductive layer. The control gate (word line) 110 is constituted by a doped polysilicon layer, and a metal layer or a silicide layer, for example.

The floating gate 112 is disposed under the control gate 110 and located on the active area 108a between the adjacent isolation structures 106a. A material of the floating gate 112 is, for example, a conductive material, such as doped polysilicon and polysilicide.

The inter-gate dielectric layer 114 is disposed between the control gate 110 and the floating gate 112, for example. A material of the inter-gate dielectric layer 114 includes a dielectric material capable of trapping charges in the inter-gate dielectric layer 114, such as silicon nitride, silicon oxynitride, aluminum oxide (Al₂O₃), hafnium oxide (HfOₓ) and zirconium oxide (ZrO). The inter-gate dielectric layer 114 may be a single layer structure, or a multilayer structure containing more than one layer, such as silicon oxide/silicon nitride or silicon oxide/silicon nitride/silicon oxide.

The tunneling dielectric layer 116 is disposed between the floating gate 112 and the substrate 100, for example. A material of the tunneling dielectric layer 116 is silicon oxide, for example.

A select unit 122 is disposed in the select unit region 102b. The select unit 122 is constituted sequentially by the substrate 100, a gate dielectric layer 116a, a conductive layer 112a and a conductive layer 110a from the substrate 100 upwards.

The conductive layer 110a extends in the Y direction. The conductive layer 110a is constituted by two conductive layers, for example, but the conductive layer 110a may certainly be constituted by only one conductive layer. The conductive layer 110a is constituted by a doped polysilicon layer, and a metal layer or a silicide layer, for example.

The conductive layer 112a is disposed under the conductive layer 110a and located on the active area 108a between the adjacent isolation structures 106a. A material of the conductive layer 112a is, for example, a conductive material, such as doped polysilicon or polysilicide.

The gate dielectric layer 116a is disposed, for example, between the conductive layer 112a and the substrate 100. A material of the gate dielectric layer 116a is, for example, silicon oxide.

A charge trapping layer 114a is disposed in the select unit region 102b of the substrate 100. A material of the charge trapping layer 114a includes a dielectric material capable of trapping charges in the charge trapping layer 114a, such as silicon nitride, silicon oxynitride, aluminum oxide (Al₂O₃), hafnium oxide (HfOₓ) and zirconium oxide (ZrO). The charge trapping layer 114a may be a single layer structure, or a multilayer structure containing more than one layer, such as silicon oxide/silicon nitride or silicon oxide/silicon nitride/silicon oxide. The charge trapping layer 114a has an opening 120 to electrically connect the second conductive layer 110a with the conductive layer 112a. As shown by an area covered by dotted lines in the memory cell region 102 of FIG. 1A, the charge trapping layer 114a at least covers an interface between the isolation structures 106a and the conductive layer 112a.

A semiconductor device 124 (transistor) is disposed in the peripheral circuit region 104. The semiconductor device 124 is disposed on the substrate 100 and located on the active area 108b between two adjacent isolation structures 106b. The semiconductor device 124 is constituted sequentially by the substrate 100, a gate dielectric layer 116b, a conductive layer 112b, and a conductive layer 110b from the substrate 100 upwards.

The conductive layer 110b extends in the Y direction across the two isolation structures 106b. The conductive layer 110b is constituted by two conductive layers, for example, but the conductive layer 110b may certainly be constituted by only one conductive layer. A material of the conductive layer 110b is constituted by a doped polysilicon layer and a metal layer or a silicide layer, for example.

The conductive layer 112b is disposed under the conductive layer 110b and located on the active area 108b between the adjacent isolation structures 106b. A material of the conductive layer 112b is a conductive material, such as doped polysilicon or polysilicide.

The gate dielectric layer 116b is disposed, for example, between the conductive layer 112b and the substrate 100. A material of the gate dielectric layer 116b is, for example, silicon oxide.

A charge trapping layer 114b is disposed in the peripheral circuit region 104. A material of the charge trapping layer 114b includes a dielectric material capable of trapping charges in the charge trapping layer 114b, such as silicon nitride, silicon oxynitride, aluminum oxide (Al₂O₃), hafnium oxide (HfOₓ) and zirconium oxide (ZrO). The charge trapping layer 114b may be a single layer structure, or a multilayer structure containing more than one layer, such as silicon oxide/silicon nitride or silicon oxide/silicon nitride/silicon oxide. The charge trapping layer 114b has an opening 126 to electrically connect the conductive layer 110b with the conductive layer 112b. As shown by an area covered by dotted lines in the peripheral circuit region 104 of FIG. 1A, the charge trapping layer 114b at least covers an interface between the isolation structures 106a and the conductive layer 112b.

According to the foregoing embodiment, materials of the floating gate 112, the conductive layer 112a and the conductive layer 112b may be the same or different. When the materials of the floating gate 112, the conductive layer 112a, and the conductive layer 112b are the same, the floating gate 112 and the conductive layers 112a and 112b may be manufactured by the same process. Materials of the control gate 110, the conductive layer 110a and the conductive layer 110b may be the same or different. When the materials of the control gate 110, the conductive layers 110a and 110b are the same, the control gate 110 and the conductive layers 110a and 110b may be manufactured by the same process.

The materials of the inter-gate dielectric layer 114, the charge trapping layer 114a and the charge trapping layer 114b may be the same or different.

When the materials of the inter-gate dielectric layer 114, the charge trapping layer 114a and the charge trapping layer 114b are the same, the inter-gate dielectric layer 114, the charge trapping layers 114a and 114b may be manufactured by the same process.

In the memory device of the present invention, since an interface between the isolation structures 106a and the conductive layer 112a is covered by the charge trapping layer 114a in the select unit 122, negative charges are trapped in the charge trapping layer 114a to seduce positive charges on a surface of the substrate 100 and reduce an electrical field of the substrate 100 contacting a top edge corner of the isolation structures 106a so that the kink effect is restrained.

In the semiconductor device of the present invention, an interface between the isolation structures 106b and the conductive layer 112b is covered by the charge trapping layer 114b, and thus negative charges are trapped in the charge trapping layer 114b to seduce positive charges on the surface of the substrate 100 and reduce an electrical field of the substrate 100 contacting a top edge corner of the isolation structures 106b so that the kink effect is restrained.

A manufacturing method of the memory device in the present invention is described in the following.

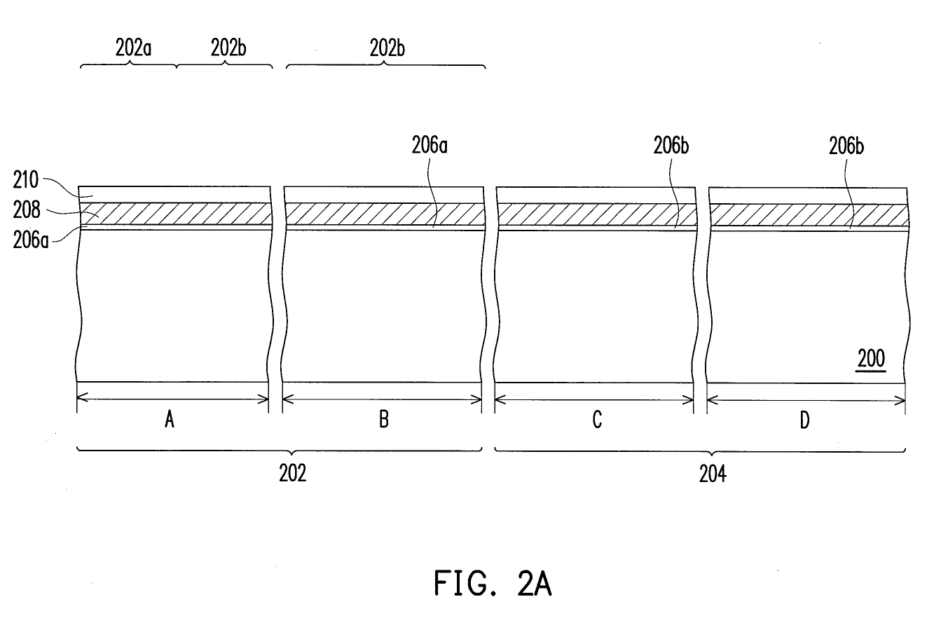

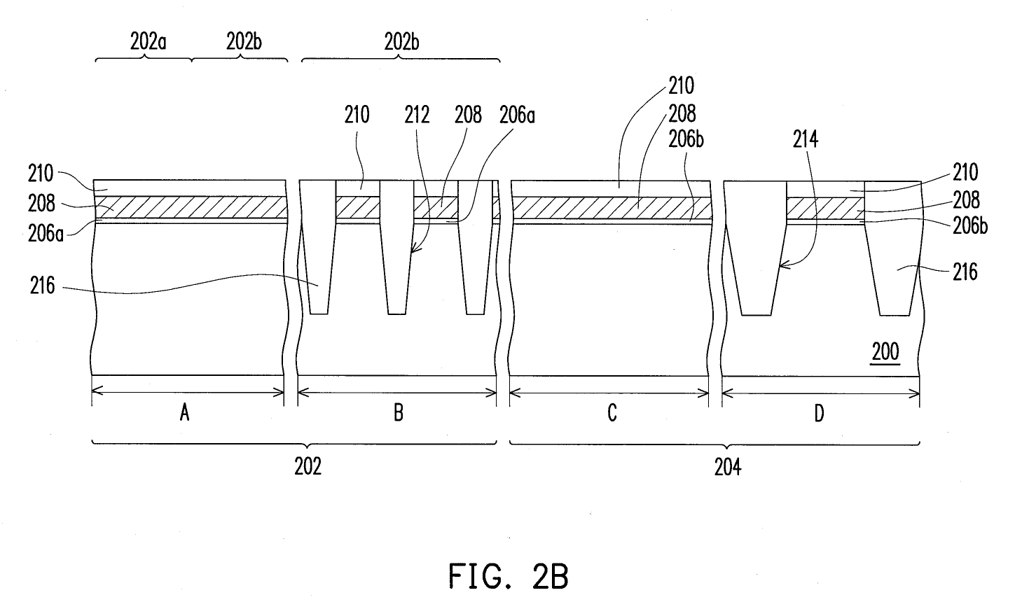

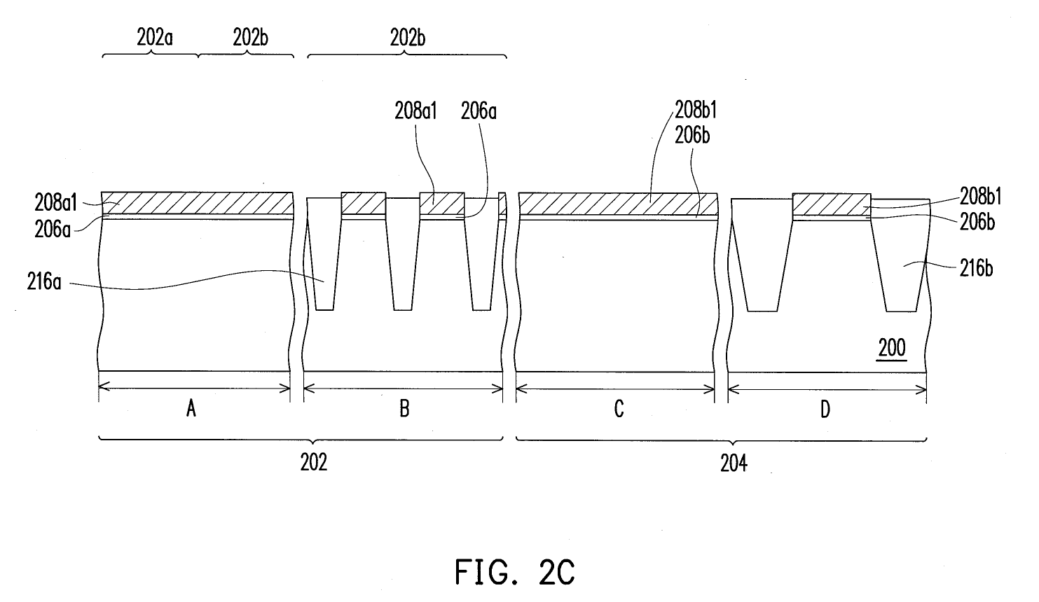

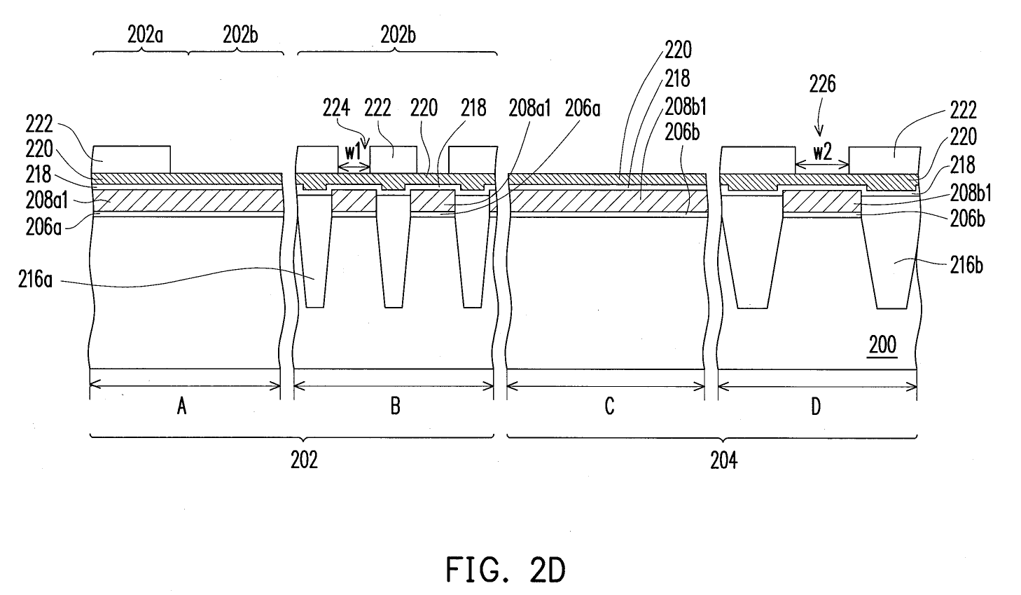

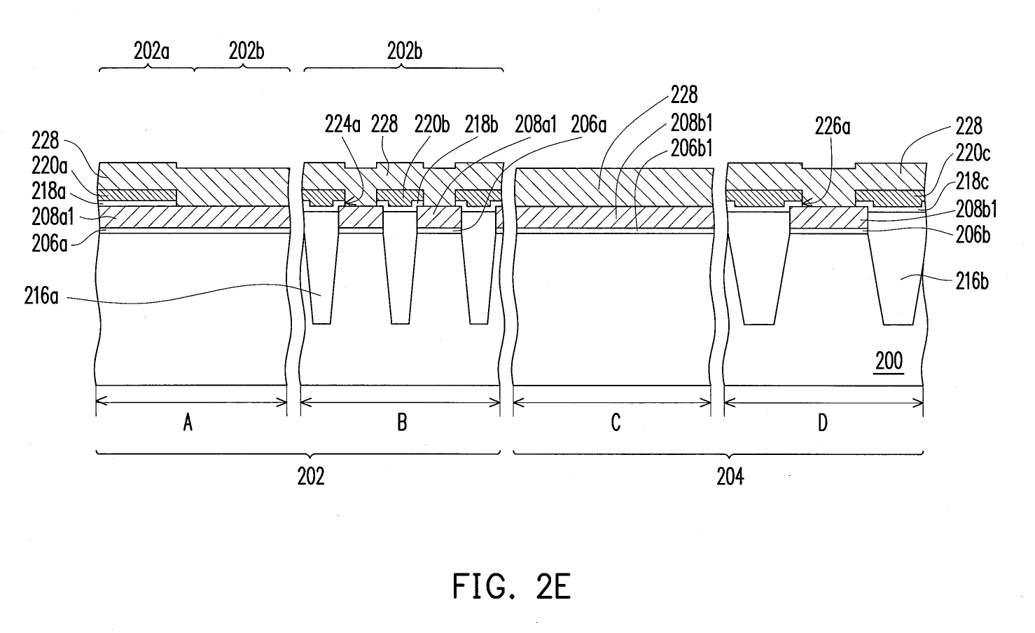

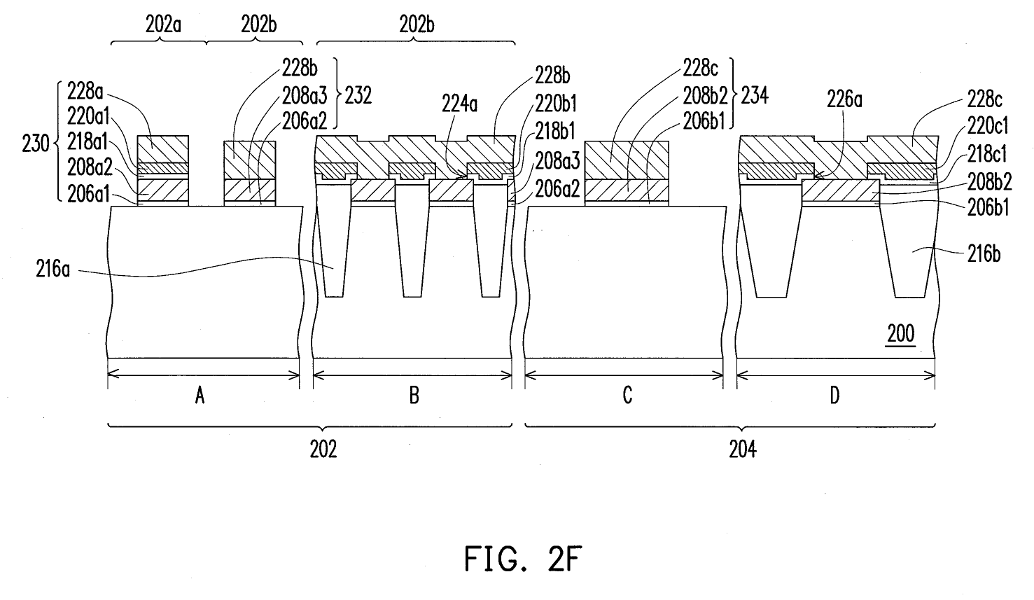

FIGS. 2A through 2F are schematic cross-sectional views showing a process of a non-volatile memory according to a preferred embodiment of the present invention. In FIGS. 2A through 2F, a section A is a schematic cross-sectional view of FIG. 1A along sectioning lines A-A′. A section B is a schematic cross-sectional view of FIG. 1A along sectioning lines B-B′. A section C is a schematic cross-sectional view of FIG. 1A along sectioning lines C-C′. A section D is a schematic cross-sectional view of FIG. 1A along sectioning lines D-D′.

Referring to FIG. 2A, a substrate 200 is provided first. The substrate 200 is divided into a memory cell region 202 and a peripheral circuit region 204. The memory cell region 202 is further divided into a memory unit region 202a and a select unit region 202b.

Afterwards, a dielectric layer 206a is formed on the substrate 200 of the memory cell region 202. A dielectric layer 206b is formed on the substrate 200 of the peripheral circuit region 204. A material of the dielectric layers 206a and 206b is silicon oxide, for example. Thicknesses of the dielectric layers 206a and 206b vary according to device characteristics. Any known methods in the prior art may be employed to form the dielectric layers 206a and 206b of different thicknesses in the memory cell region 202 and the peripheral circuit region 204. The present embodiment is exemplified by forming the dielectric layer 206a of a thickness on the memory cell region 202. Certainly, the dielectric layer 206a on the memory unit region 202a and the select unit region 202b may also have different thicknesses respectively pursuant to actual requirements. Any known methods in the prior art may certainly be employed to form the dielectric layer 206a of different thicknesses in the memory unit region 202a and the select unit region 202b.

Thereafter, a conductive material layer 208 is formed on the entire substrate 200. A material of the conductive material layer 208 is doped polysilicon or polysilicide, for example. When the material of the conductive material layer 208 is doped polysilicon, a method of forming the conductive material layer 208 includes first performing a chemical vapor deposition (CVD) process to form an un-doped polysilicon layer and then performing an ion implantation process. Or, the conductive material layer 208 may be formed by performing an in-situ ion implanting process followed by a CVD process.

Then, a mask layer 210 is formed on the entire substrate 200. A material of the mask layer 210 is, for example, silicon nitride, and the mask layer 210 is formed by performing a CVD process, for example.

Referring to FIG. 2B, the mask layer 210 is patterned to form an opening exposing the conductive material layer 208. Then, the conductive material layer 208, the dielectric layers 206a and 206b, and the substrate 200 are etched by using the mask layer 210 as a mask to form a plurality of trenches 212 and 214 in the substrate 200. Next, an insulating material layer 216 is formed on the substrate 200. The insulating material layer 216 fills up the trenches 212 and 214. A material of the insulating material layer 216 is silicon oxide formed by performing a high-density plasma chemical vapor deposition (HDPCVD) process, for example. Afterwards, a chemical-mechanical polishing process is performed by using the mask layer 210 as a polishing stop layer to remove the redundant insulating material layer 216.

Referring to FIG. 2C, the mask layer 210 and a portion of the insulating material layer 216 are removed to form isolation structures 216a in the substrate 200 of the memory cell region 202 and form isolation structures 216b in the substrate 200 of the peripheral circuit region 204 so as to define active areas. Top surfaces of the isolation structures 216a and 216b are lower than top surfaces of the conductive material layer 208. The isolation structures 216a separate the conductive material layer 208 to form conductive layers 208a1 on the substrate 200 of the memory cell region 202. The isolation structures 216b separate the conductive material layer 208 to form conductive layers 208b1 on the substrate 200 of the peripheral circuit region 204.

Referring to FIG. 2D, a charge trapping layer 218 is formed on the substrate 200. A material of the charge trapping layer 218 includes a dielectric material capable of trapping charges in the charge trapping layer 218, such as silicon nitride, silicon oxynitride, aluminum oxide (Al₂O₃), hafnium oxide (HfOₓ) and zirconium oxide (ZrO). The charge trapping layer 218 may be a single layer structure, or a multilayer structure containing more than one layer, such as silicon oxide/silicon nitride or silicon oxide/silicon nitride/silicon oxide. When the charge trapping layer 218 consists of silicon oxide/silicon nitride/silicon oxide layers, a method of forming the charge trapping layer 218 includes first forming a bottom silicon oxide layer by a thermal oxidation process, followed by forming a silicon nitride layer by a CVD process and then forming a top silicon oxide layer on the silicon nitride layer.

Subsequently, another conductive material layer 220 is formed on the substrate 200. A material of the conductive material layer 220 is, for example, doped polysilicon or polysilicide. When the material of the conductive material layer 220 is doped polysilicon, a method of forming the conductive material layer 220 includes first forming an un-doped polysilicon layer by performing a CVD process and then performing an ion implanting process. Or, the conductive material layer 220 may be formed by first performing an in-situ ion implanting process followed by a CVD process.

Afterwards, a patterned photoresist layer 222 is formed on the substrate 200. The patterned photoresist layer 222 covers the entire memory unit region 202a. The patterned photoresist layer 222 has an opening 224 and an opening 226 in the select unit region 202b and the peripheral circuit region 204 respectively. The opening 224 is disposed over the conductive layer 208a1 between two adjacent isolation structures 216a. A width W1 of the opening 224 is smaller than a distance between the two adjacent isolation structures 216a. The opening 226 is disposed over a conductive layer 208b1 between two adjacent isolation structures 216b. A width W2 of the opening 226 is smaller than a distance between the two adjacent isolation structures 216b. A method of forming the patterned photoresist layer 222 includes forming a photoresist material layer on the entire substrate 200 first. Later, an exposure process and a development process are performed to form the patterned photoresist layer 222.

Referring to FIG. 2E, a portion of the conductive material layer 220 and a portion of the charge trapping layer 218 in the select unit region 202b and the peripheral circuit region 204 are removed by using the patterned photoresist 222 as a mask to leave a conductive layer 220a and a charge trapping layer 218a in the memory unit region 202a, leave a conductive layer 220b and a charge trapping layer 218b in the select unit region 202b, and leave a conductive layer 220c and a charge trapping layer 218c in the peripheral circuit region 204. The conductive layer 220b and the charge trapping layer 218b in the select unit region 202b have an opening 224a to expose the conductive layer 208a1. The charge trapping layer 218b at least covers an interface between the isolation structures 216a and the conductive layer 208a1. The conductive layer 220c and the charge trapping layer 218c in the peripheral circuit region 204 have an opening 226a to expose the conductive layer 208b1. The charge trapping layer 218c at least covers an interface between the isolation structures 216b and the conductive layer 208b1. A portion of the conductive layer 220 and a portion of the charge trapping layer 218 on the select unit region 202b and the peripheral circuit region 204 are removed by an etching process, for example.

Next, the patterned photoresist layer 222 is removed. A method of removing the patterned photoresist layer 222 includes, for example, performing a wet photoresist etching process or a dry photoresist etching process. After removing the patterned photoresist layer 222, a conductive material layer 228 is formed on the substrate 200. A material of the conductive material layer 228 includes silicide of refractory metals selected from a group consisting of nickel, cobalt, titanium, copper, molybdenum, tantalum, tungsten, erbium, zirconium, platinum and a silicide of any alloy of the foregoing metals. A method of forming the conductive material layer 228 includes, for example, performing a physical vapor deposition (PVD) process or a CVD process.

Referring to FIG. 2F, the conductive material layer 228, the conductive layers 220a and 220b, the charge trapping layers 218a and 218b, the conductive layer 208a1 and the dielectric layer 206a in the memory cell region 202 are patterned to form a memory unit 230 and a select unit 232 respectively in the memory unit region 202a and the select unit region 202b. Meanwhile, the conductive material layer 228, the conductive layer 220c, the charge trapping layer 218c, the conductive layer 208b1 and the dielectric layer 206b in the peripheral circuit region 204 are patterned to form a gate structure 234.

The memory unit 230 is constituted by a conductive 228a, a conductive 220a1, a charge trapping layer 218a1, a conductive layer 208a2 and a dielectric layer 206a1. The conductive layers 228a and 220a1 serve as a control gate. The charge trapping layer 218a1 serves as an inter-gate dielectric layer. The conductive layer 208a2 serves as a floating gate. The dielectric layer 206a1 serves as a tunneling dielectric layer.

The select unit 232 is constituted by a conductive layer 228b, a conductive layer 220b1, a conductive layer 208a3 and a dielectric layer 206a2. The conductive layers 228b, 220b1 and 208a3 serve as a gate. The dielectric layer 206a2 serves as a gate dielectric layer. The charge trapping layer 218b1 in the select unit 232 covers an interface between the isolation structures 216a and the conductive layer 208a3 to restrain the kink effect.

The gate structure 234 (a semiconductor device) is constituted by a conductive layer 228c, a conductive layer 220c1, a conductive layer 208b2 and a dielectric layer 206b1. The conductive layers 228c, 220c1 and 208b2 serve as a gate. The dielectric layer 206b1 serves as a gate dielectric layer. The charge trapping layer 218c in the gate structure 234 covers an interface between the isolation structures 216b and the conductive layer 208b2 to restrain the kink effect.

The present embodiment is exemplified by forming the memory unit 230, the select unit 232 and the gate structure 234 by the same patterning process. Certainly, the memory unit 230, the select unit 232 and the gate structure 234 may also be formed by different patterning processes respectively.

The present embodiment is exemplified by forming a conductive layer 220 on the charge trapping layer 218. Conceivably, in the present invention, the charge trapping layer 218 may also be patterned by directly using the patterned photoresist layer 222 without forming the conductive layer 220.

According to the manufacturing method of the memory device in the present invention, since the interface between the isolation structures 216a (216b) and the conductive layer 208a3 (208b2) is covered by the charge trapping layer 218b (218c), negative charges are trapped in the charge trapping layer 218b (218c) to seduce positive charges on the surface of the substrate and reduce the electrical field of the substrate contacting the top edge corner of the isolation structures so that the kink effect is restrained. When the charge trapping layer 218b (218c) also serves as the inter-gate dielectric layer of the memory unit, the kink effect is restrained without changing the process of the memory device.

Accordingly, in the memory device and the manufacturing method thereof in the present invention, the interface between the isolation structures and the conductive layer is covered by the charge trapping layer, and thus negative charges are trapped in the charge trapping layer to seduce positive charges on the surface of the substrate and reduce the electrical field of the substrate contacting the top edge corner of the isolation structures so that the kink effect is restrained. When the charge trapping layer also serves as an inter-gate dielectric layer, the kink effect is restrained without changing the process of the memory device.

In the semiconductor device of the present invention, the interface between the isolation structures and the conductive layer is covered by the charge trapping layer, and thus negative charges are trapped in the charge trapping layer to seduce positive charges on the surface of the substrate and reduce the electrical field of the substrate contacting the top edge corner of the isolation structures so that the kink effect is restrained. Moreover, the manufacturing method of the semiconductor device in the present invention is simpler.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A memory device, disposed on a substrate having a memory unit region and a select unit region, comprising:
a plurality of isolation structures, disposed in the substrate;
a memory unit, disposed in the memory unit region, comprising a tunneling dielectric layer, a floating gate, an inter-gate dielectric layer and a control gate sequentially disposed on the substrate;
a select unit, disposed in the select unit region, comprising a gate dielectric layer, a first conductive layer and a second conductive layer sequentially disposed on the substrate; and
a charge trapping layer, disposed in the select unit region, wherein the charge trapping layer has an opening to electrically connect the second conductive layer with the first conductive layer, and the charge trapping layer at least covers an interface between the isolation structures and the first conductive layer.

2. The memory device as claimed in claim 1, wherein a material of the charge trapping layer is selected from a group consisting of silicon nitride, silicon oxynitride, aluminum oxide (Al₂O₃), hafnium oxide (HfOₓ) and zirconium Oxide(ZrO).

3. The memory device as claimed in claim 1, wherein the charge trapping layer is a silicon oxide/silicon nitride/silicon oxide layer.

4. The memory device as claimed in claim 1, wherein a material of the charge trapping layer is the same as a material of the inter-gate dielectric layer.

5. The memory device as claimed in claim 1, wherein a material of the first conductive layer is the same as a material of the floating gate.

6. The memory device as claimed in claim 1, wherein a material of the second conductive layer is the same as a material of the control gate.

7. A manufacturing method of a memory device, comprising:
providing a substrate having a memory unit region and a select unit region, wherein a plurality of isolation structures have been formed in the substrate, and a dielectric layer and a first conductive layer have been formed on the substrate between adjacent isolation structures;
forming a charge trapping layer on the substrate;
removing a portion of the charge trapping layer in the select unit region to form a first opening exposing the first conductive layer, wherein the remaining charge trapping layer in the select unit region at least covers an interface between the isolation structures and the first conductive layer;
forming a second conductive layer on the substrate; and
patterning the second conductive layer, the charge trapping layer, the first conductive layer and the dielectric layer to form a memory unit in the memory unit region and form a select unit in the select unit region.

8. The manufacturing method of the memory device as claimed in claim 7, wherein a material of the charge trapping layer is selected from a group consisting of silicon nitride, silicon oxynitride, aluminum oxide (Al₂O₃), hafnium oxide (HfOₓ) and zirconium oxide (ZrO).

9. The manufacturing method of the memory device as claimed in claim 7, wherein the charge trapping layer is a silicon oxide/silicon nitride/silicon oxide layer.

10. The manufacturing method of the memory device as claimed in claim 7, wherein the charge trapping layer in the memory unit serves as an inter-gate dielectric layer.

11. The manufacturing method of the memory device as claimed in claim 7, wherein the step of forming the isolation structures in the substrate and forming the dielectric layer and the first conductive layer on the substrate between the adjacent isolation structures comprises:
forming a dielectric material layer, a conductive material layer and a mask layer on the substrate;
patterning the mask layer, the conductive material layer, the dielectric material layer and the substrate to form a plurality of trenches in the substrate;
filling in an insulating material layer in the trenches; and
removing a portion of the insulating material layer and the mask layer to form the isolation structures.

12. The manufacturing method of the memory device as claimed in claim 7, wherein the substrate further comprises a peripheral circuit region, the manufacturing method further comprising:
removing simultaneously a portion of the charge trapping layer in the peripheral circuit region in the step of removing a portion of the charge trapping layer in the select unit region, the remaining charge trapping layer in the peripheral circuit region at least covering the interface between the isolation structures and the first conductive layer; and
forming a semiconductor device in the peripheral circuit region simultaneously in the step of patterning the second conductive layer, the charge trapping layer, the first conductive layer and the dielectric layer.

13. A semiconductor device, disposed on a substrate, comprising:
two isolation structures, disposed in the substrate;
a second conductive layer, disposed on the substrate across the two isolation structures;
a first conductive layer, disposed between the two isolation structures and between the second conductive layer and the substrate, the first conductive layer electrically connected to the second conductive layer;
a charge trapping layer, disposed on the substrate and at least covering an interface between the two isolation structures and the first conductive layer; and
a gate dielectric layer disposed between the first conductive layer and the substrate.

14. The semiconductor device as claimed in claim 13, wherein a material of the charge trapping layer is selected from a group consisting of silicon nitride, silicon oxynitride, aluminum oxide (Al₂O₃), hafnium oxide (HfOₓ) and zirconium Oxide(ZrO).

15. The semiconductor device as claimed in claim 13, wherein the charge trapping layer is a silicon oxide/silicon nitride/silicon oxide layer.
